(19) United States
(12) Patent Application Publication
(10) Pub. No.: US 2012/0057726 A1
(43) Pub. Date: Mar. 8, 2012

(54) Sound volume limiter using continuous evaluation of the incurred sound exposure dose to prevent hearing damage without degrading the user experience

(76) Inventor: Sander Jeroen van Wijngaarden, The Hague (NL)

(21) Appl. No.: 12/875,190

(22) Filed: Sep. 3, 2010

(51) Int. Cl. H03G 3/00

(52) U.S. Cl. 381/107

(57) ABSTRACT

A system and method is described for automatically limiting the sound exposure incurred by users of sound reproducing devices, by continuously tracking and evaluating the cumulative sound exposure dose. Instead of limiting the average sound level to a fixed maximum, the user retains freedom to adjust the sound volume to higher or lower levels. However, if the system determines that the overall cumulative sound dose is approaching a certain pre-set value presumed to be potentially hazardous, the gain and compression settings of the sound reproducing device are modified in order to limit sound exposure. This is done in such a way that the interference with the user experience is minimized. Optionally, the user is also provided with controls to temporarily boost the sound level, which then gradually falls back to a level that is acceptable for prolonged exposure. The sound limiting system starts acting more quickly and aggressively as the tracked sound exposure dose becomes higher.

### BACKGROUND

Portable audio devices, such as MP3 players, have become ubiquitous. Many people now wear headphones or earphones for a considerable amount of time each day, not only when listening to music but also while using their cell phone or portable game console. There is also a clear trend that children start using these devices at an ever younger age. Numerous studies indicate that volume controls are quite commonly set to produce hazardously high sound pressure levels. It has also been well established that prolonged exposure to higher sound pressure levels leads, over time, to permanent and irreversible hearing loss. In fact, for this reason many suppliers started adding some type of “volume limiter” functionality to the products many years ago. This has not prevented the number of people with noise-induced hearing loss attributed to personal audio devices from increasing.

Common volume limiters suffer from a few inherent drawbacks. Users tend to accept them only if there is some kind of “override” available. A device that does not give the user the option to play back sound as loudly as desired by the user is not likely to be a commercial success. In practice, people who prefer their music (too) loud now simply disable the limiting system. Volume limiters are perceived as interfering with the intended experience. Demographically, the groups most likely to be at risk are young people (children and teenagers), who tend to use audio devices often, for relatively long periods, and at high sound levels. Moreover, their hearing tends to be sharper to begin with, which also means that they are more suscepptible to the damaging effects of high sound levels. Precisely this group has a markedly negative attitude towards sound volume limiters.

What is needed is a solution that is not perceived as annoying or undesirable, but still effective in preventing that an overall, cumulative sound exposure is incurred that is potentially damaging.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

The disclosed invention is an electronic sound volume limiting system based on a running calculation of the incurred sound exposure dose. This sound limiting system is applied as an added feature, in the form of hard- and/or software, to a sound reproducing device. The sound volume limiting system keeps track of the sound pressure levels generated by the sound reproducing system over the course of 8 or 24 hours. The system therefore “knows” the degree of sound exposure incurred sofar. The system also controls the gain and compression parameters of the sound reproducing device. Using sound exposure metrics which predict the risk of hearing damage (such as given by ISO 1999), the system knows how the risk of hearing damage is modified when it adjusts gain and compression settings. The system then deploys smart strategies that limit the overall sound exposure, but are not experienced as annoying or even perceived at all by the user. As a certain preset limit for 8 or 24-hour exposure is approached, the system becomes more aggressive in reducing sound pressure levels.

Optional features of this invention also include (1) the use measured ambient sound levels in adjusting the sound pressure level of the sound reproducing system, (2) using age-specific profiles and frequency weighting functions when assessing the sound exposure dose, and (3) various strategies for adjusting gain and compression parameters in order to reduce sound exposure dose.

These and other features will be addressed in greater detail below.

### BRIEF DESCRIPTION OF THE DRAWING

FIG. 1 is a block diagram of the limiting system

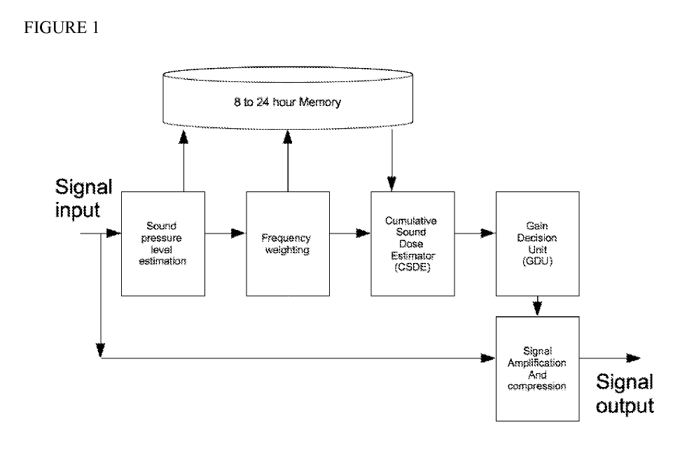

### DETAILED DESCRIPTION

The invention disclosed is in essence a volume limiting system that does not limit the instantaneous sound level, but rather imposes limits on the cumulative sound dose incurred by the user of a sound repoducing system. This can be implemented in hardware or software. For example, the system can be implemented in hardware as a component of a headset, headphones or earphones, or in software as part of the audio input/output module of an MP3 player or portable game console.

The implementation of common existing sound level limiting algorithms can be broken down into the following successive steps:

1. Estimation of the produced sound pressure level at a given instant

2. (optionally) application of frequency-weighting or filtering to sound pressure level estimates

3. (optionally) computing average sound level, or equivalent-continuous sound levels, from a successive series of instantaneous sound pressure level estimates. This typically occurs over a time scale of several seconds at most.

4. Immediately adjusting the signal gain or signal compression settings in such a way that the resulting estimated sound pressure level remains below a certain level, corresponding to the maximum allowable sound pressure level.

Hence, common existing systems have no memory beyond the time scale of the averaging window, which is in the order of seconds. If the average sound pressure level varies slowly over time (in the order of minutes), as may be the case due to the dynamics of music or due to differences between successive songs, then the effective gain and compression settings will be adjusted to always keep the sound pressure level just below the preset limit. As long as the limiting system remains enabled, source sounds that would lead to sound pressure levels above the preset threshold are played back equally loudly.

The algorithm of the disclosed invention, described below, shows markedly different behavior:

1. The algorithm continually estimates the produced sound pressure level at any given instant, and stores this in memory. The total memory capacity is such that at least 8 to 24 hours of sound pressure level estimates can be stored.

2. Frequency weighting is applied to take the sensitivity of the human ear into account. Optionally, the weighting profile is adjusted to the specific sensitivity characteristic applicable for the age group of the user.

3. At chosen time intervals, the cumulative noise dose incurred by the user over the last 8 or 24 hours is calculated. This is done using an algorithm for calculating the risk of sound-induced hearing loss from series of instantaneous sound pressure level measurements, such as the algorithm specified in ISO 1999: 1990 (Acoustics—Determination of occupational noise exposure and estimation of noise-induced hearing impairment. This step is carried out by a module called the Cumulative Sound Dose Estimator (CSDE)

4. The output from the CSDE is fed into the a module called the Gain Decision Unit (GDU). This unit decides, based on information on how the incurred noise dose is developing over time, whether the gain and compression settings are to be adjusted

5. Gain and compression settings are updated according to output from the GDU.

6. Optionally, the user is provided with controls to temporarily override the GDU decision by boosting the signal for a limited amount of time. This override option can be presented to the user in the form of a physical button or a software setting. The effect achieved by overriding the GDU is a temporary increase in loudness, which is gradually diminished over the course of minutes through intervention by the GDU during successive processing cycles. To the user, this offers the possibility to temporarily enhance the experience of a particular song or scene. The resulting effect on the accumulated sound dose is accounted for by the system. The GDU is programmed to make sure that to higher the overall dose becomes, the smaller the boost-effect of using the override option is. Hence, the user is rewarded for using this option sparingly, yet always retains freedom to boost the sound level to enhance the experience.

The risk of sound-induced hearing loss is predicted far more accurately by the cumulative sound exposure dose metrics (such as the one given in ISO 1999) than by the instantaneous sound level. To the user, the attractiveness of the disclosed invention lies in the fact that the system manages (and limits) the risk of hearing damage, without taking away the freedom of the user to enhance his experience by means of (temporarily) adjusting the volume control. Moreover, succesive segments of sound (succesive songs or scenes) may still vary in sound pressure level. The quieter segments are used to save up sound exposure quotum, to allow the more exciting segments to be played back more loudly.

The Gain Decision Unit can be programmed to exhibit different strategies towards achieving the desired effect, which is always: limiting the cumulative sound dose. Some different strategies, which can be applied separately or at the same time, are:

1. Gradually and slowly decreasing the gain, and therefore the average sound level, over the course of the first minutes (typically 5-15 minutes) after the the sound reproducing system is switched on. A slow decrease in sound level is imperceptible to the user, hence the user remains unaware that the gain is being reduced. High sound levels are mostly selected (and preferred) immediately upon the beginning of sound playback. Somewhat lower sound levels tend to be acceptable later on.

2. Stepwise reduction of the gain between sound segments, in small steps of typically 1 to 3 dB. Reduction of the gain in periods of silence is imperceptible, provided that the gain steps are sufficiently small.

3. Application of signal compression settings that effectively impose a lower limit to the sound level of quiet passages. Passages with very low sound levels tend to encourage users to increase the sound volume. By making sure that even quiet passages are always sufficiently loud, the system decreases the likelihood that the user will select a higher sound volume setting.

4. Automatic recognition of high-intensity, high-power segments, which are then automatically boosted by the system. The acceptability to the user of the overall sound level is mainly determined by the behavior of the limiting system during such “power segments.” The user is likely to leave the overall volume setting unchanged if those passages are perceived as sufficiently loud.

5. Taking the effect of ambient sounds into account. Human perception of loudness is strongly influenced by acoustic references. A sound of a given sound pressure level is perceived to be (much) louder in a silent environment that in a noisy environment. By measuring ambient sound pressure levels, and taking these into account as a reference, the system is able to better predict the perceived loudness of sounds to the user. This way, if the environment of the user becomes quiter, the gain of the sound reproducing is reduced without the user becoming aware—reducing, however, the incurred sound exposure dose. The use of ambient sound pressure level measurements is particularly attractive when the sound reproducing device already features an external microphone that can be used for this; this is the case with many devices nowadays, e.g. smartphones and game consoles.

6. As the maximum allowable sound exposure dose is approached, the system becomes more aggressive and rapid-acting in adjusting gain and compression settings.

The above strategies can be used without providing the user any kind of feedback on interventions of the limiting system. Optionally, the system can be constructed in such a way that the user is informed of the actions of the system, the incurred sound exposure dose sofar, and other relevant measures and parameters.

What is claimed is:

1. An electronic sound volume limiting system, comprising software or hardware which dynamically limits the sound level produced by a sound reproducing device, headset, headphones or earphones, based on a calculated cumulative sound exposure dose incurred by the user of said device, headset, headphones or earphones, in comparison to a preset maximum threshold corresponding to a certain maximum cumulative sound exposure dose

2. An electronic sound volume limiting system as described in claim 1, further comprising a subsystem which continually keeps track of measurements, calculations and parameter settings and stores these over a period of 8 to 24 hours for the purpose of continually calculating and updating sound exposure dose

3. An electronic sound volume limiting system as described in claim 1, further comprising the possibility to visualize and/or auralize and/or electronically download sound exposure data from the system, including logged instantaneous sound levels as a function of time and the overall sound level as a function of time

4. An electronic sound volume limiting system as described in claim 1, further comprising the added functionality of offering the user the possibility to select the maximum sound exposure threshold and other parameters of the sound volume limiting system

5. An electronic sound volume limiting system as described in claim 1, further comprising an override option by means of a button, switch or software setting, which allows a temporary increase in sound level for a limited time period, while still restricting the overall cumulative dose to remain below the preset maximum threshold.

6. An electronic sound volume limiting system as described in claim 1, further comprising calculation profiles or frequency weighting schemes which take the age of the user into account in order to calculate age-dependent sound exposure dose estimates and/or sound exposure limits.

7. An electronic sound volume limiting system as described in claim 1, further comprising strategies which reduce sound pressure levels imperceptibly to the user including gradually decreasing the signal gain and decreasing gain during periods of silence

8. An electronic sound volume limiting system as described in claim 1, further comprising functionality to automatically and temporarily increase the sound pressure level during segments which are expected, based on signal characteristics or meta-information, to be perceived as high-power and high-intensity segments and for which the sound pressure level has higher relative importance to the overall user experience
